(19) United States
(12) Patent Application Publication
(10) Pub. No.: US 2005/0023672 A1
(43) Pub. Date: Feb. 3, 2005

(54) Device and method for immersed array packaging and processing

(75) Inventors: Clifford A. Oostman, Quilcene, WA (US); Melvin Yamamoto, Fremont, CA (US)

Correspondence Address: AFFYMETRIX, INC;ATTN: CHIEF IP COUNSEL, LEGAL DEPT., 3380 CENTRAL EXPRESSWAY, SANTA CLARA, CA, 95051, US

(73) Assignee: Affymetrix, INC., Santa Clara, CA (US)

(21) Appl. No.: 10/884,125

(22) Filed: Jul. 1, 2004

Related U.S. Application Data
(60) Provisional application No. 60/484,401, filed on Jul. 1, 2003.

(51) Int. Cl. H01L 23/053; H01L 23/12

(52) U.S. Cl. 257/701

(57) ABSTRACT

The present invention provides devices and methods for packaging and processing an immersed microarray chip. In one embodiment, the present invention provides a device comprising a chip mounted on a peg to form a sensor peg, and a sensor cartridge well into which the sensor peg is immersed for processing.

### REFERENCES TO RELATED APPLICATIONS

The present application claims the priority of U.S. Provisional Application Ser. No. 60/484,401, filed on Jul. 1, 2003, and is related to U.S. patent application Ser. No. 10/826,577, entitled “Immersion Array Plates for Interchangeable Microtiter Well Plates”, filed on Apr. 16, 2004. The entire contents of these applications are incorporated herein by reference.

### FIELD OF THE INVENTION

The present invention relates to the packaging of biological assays. More particularly, the present invention relates to packaging devices and methods for nucleic acid assays.

### BACKGROUND OF THE INVENTION

The field of nucleic acid assays has been transformed by microarrays which allow extremely high-throughput and parallel monitoring of gene expression events, expression profiling, diagnostics and large-scale, high-resolution genotyping analyses, among other applications. Substrates bearing arrays of probes (fragments of nucleic acids) need to be packaged and optimally processed in a manner that allows assays such as expression monitoring, genotyping and other studies to be performed accurately and efficiently. Packaging devices for microarrays may comprise, for example, a sealed chamber containing inlets for the introduction of fluids. With higher-throughput and more sensitive applications being contemplated for microarrays in the fields of pharmacogenomics and diagnostics, for example, there exists a need in the art for additional devices for packaging and processing microarrays.

### SUMMARY OF THE INVENTION

In one aspect of the invention, a device for packaging and processing a microarray chip is provided. The device comprises a peg member; a sensor; wherein the sensor is mounted on the peg member to form a sensor peg; and at least one cartridge; wherein the sensor peg is immersed into the cartridge for a plurality of processing steps. In a preferred embodiment, the sensor is a microarray chip.

In one embodiment of the sensor peg design, the peg member is rectangular and the associated cartridge is also rectangular. In this embodiment, the sensor is mounted coplanarly on the rectangular peg member such that the sensor peg is immersed vertically into the cartridge. In some embodiments, the sensor may be mounted with an adhesive. The peg member and cartridge may be made of plastic. In yet other embodiments, the rectangular sensor peg is sealed to the cartridge.

In another embodiment of the sensor peg design, the peg member is cylindrical and the associated cartridge is also correspondingly cylindrical. In this embodiment, the sensor is mounted horizontally onto the bottom of the cylindrical peg member. In some embodiments, the sensor is mounted with an adhesive. The peg member and cartridge may be made of plastic. In other embodiments, the cylindrical sensor peg is sealed to the cartridge.

In a preferred embodiment, the cylindrical peg member of the cylindrical sensor peg includes a luer fitting feature to enable sealing by a twisting mechanism. In another preferred embodiment the cylindrical sensor peg includes a press fit feature on the peg member.

In yet another preferred embodiment, the peg sensor further comprises an identification tab, such as a label, a radio frequency identification detector (RFID) and so forth. The tab can also include a feature to enable automation or robotic handling.

In another aspect of the present invention, the sensor peg is subjected to a plurality of processing steps, including hybridization, washing, staining and scanning. Preferably, a different cartridge is used for each processing step.

In yet another aspect of the present invention, a method for processing a sensor peg is provided. The method comprises providing a plurality of cartridges containing fluids therein, sequentially immersing the sensor peg into the plurality of cartridges; and providing suitable conditions for carrying out the reaction steps of hybridization, washing, staining and scanning in the plurality of cartridges. In a preferred embodiment, the sensor peg comprises a microarray chip. The microarray chip may be 3 mm by 3 mm, for example. In another preferred embodiment, a different cartridge is used for each of the reaction steps. The device and method of the present invention allows for reduction in fluid volumes for the plurality of reaction steps. In some embodiments the volume of the fluid in a cartridge is less than 10 μl.

### BRIEF DESCRIPTION OF THE DRAWINGS

The accompanying drawings, which are incorporated in and form a part of this specification, illustrate embodiments of the invention and, together with the description, serve to explain the principles of the invention:

FIG. 1 depicts a first embodiment of the sensor peg and sensor cartridge well of the present invention.

FIG. 2 depicts a second embodiment of the sensor peg and sensor cartridge well of the present invention.

FIG. 3 depicts a third embodiment of the sensor peg and sensor cartridge well of the present invention.

### DETAILED DESCRIPTION OF THE INVENTION

I. General

The present invention has many preferred embodiments and relies on many patents, applications and other references for details known to those of the art. Therefore, when a patent, application, or other reference is cited or repeated below, it should be understood that it is incorporated by reference in its entirety for all purposes as well as for the proposition that is recited.

As used in this application, the singular form “a,” “an,” and “the” include plural references unless the context clearly dictates otherwise. For example, the term “an agent” includes a plurality of agents, including mixtures thereof.

An individual is not limited to a human being but may also be other organisms including but not limited to mammals, plants, bacteria, or cells derived from any of the above.

Throughout this disclosure, various aspects of this invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

The practice of the present invention may employ, unless otherwise indicated, conventional techniques and descriptions of organic chemistry, polymer technology, molecular biology (including recombinant techniques), cell biology, biochemistry, and immunology, which are within the skill of the art. Such conventional techniques include polymer array synthesis, hybridization, ligation, and detection of hybridization using a label. Specific illustrations of suitable techniques can be had by reference to the example herein below. However, other equivalent conventional procedures can, of course, also be used. Such conventional techniques and descriptions can be found in standard laboratory manuals such as Genome Analysis: A Laboratory Manual Series (Vols. I-IV), Using Antibodies: A Laboratory Manual, Cells: A Laboratory Manual, PCR Primer: A Laboratory Manual, and Molecular Cloning: A Laboratory Manual (all from Cold Spring Harbor Laboratory Press), Stryer, L. (1995) Biochemistry (4th Ed.) Freeman, N.Y., Gait, “Oligonucleotide Synthesis: A Practical Approach” 1984, IRL Press, London, Nelson and Cox (2000), Lehninger, Principles of Biochemistry 3^{rd} Ed., W. H. Freeman Pub., New York, N.Y. and Berg et al. (2002) Biochemistry, 5^{th} Ed., W. H. Freeman Pub., New York, N.Y., all of which are herein incorporated in their entirety by reference for all purposes.

The present invention can employ solid substrates, including arrays in some preferred embodiments. Methods and techniques applicable to polymer (including protein) array synthesis have been described in U.S. Ser. No. 09/536,841, WO 00/58516, U.S. Pat. Nos. 5,143,854, 5,242,974, 5,252,743, 5,324,633, 5,384,261, 5,405,783, 5,424,186, 5,451,683, 5,482,867, 5,491,074, 5,527,681, 5,550,215, 5,571,639, 5,578,832, 5,593,839, 5,599,695, 5,624,711, 5,631,734, 5,795,716, 5,831,070, 5,837,832, 5,856,101, 5,858,659, 5,936,324, 5,968,740, 5,974,164, 5,981,185, 5,981,956, 6,025,601, 6,033,860, 6,040,193, 6,090,555, 6,136,269, 6,269,846 and 6,428,752, in PCT Applications Nos. PCT/US99/00730 (International Publication Number WO 99/36760) and PCT/US01/04285, which are all incorporated herein by reference in their entirety for all purposes.

Patents that describe synthesis techniques in specific embodiments include U.S. Pat. Nos. 5,412,087, 6,147,205, 6,262,216, 6,310,189, 5,889,165, and 5,959,098. Nucleic acid arrays are described in many of the above patents, but the same techniques are applied to polypeptide arrays.

Nucleic acid arrays that are useful in the present invention include those that are commercially available from Affymetrix (Santa Clara, Calif.) under the brand name GeneChip®. Example arrays are shown on the Affymetrix website.

The present invention also contemplates many uses for polymers attached to solid substrates. These uses include gene expression monitoring, profiling, library screening, genotyping and diagnostics. Gene expression monitoring and profiling methods can be shown in U.S. Pat. Nos. 5,800,992, 6,013,449, 6,020,135, 6,033,860, 6,040,138, 6,177,248 and 6,309,822. Genotyping and uses therefore are shown in U.S. Ser. No. 60/319,253, 10/013,598, and U.S. Pat. Nos. 5,856,092, 6,300,063, 5,858,659, 6,284,460, 6,361,947, 6,368,799 and 6,333,179. Other uses are embodied in U.S. Pat. Nos. 5,871,928, 5,902,723, 6,045,996, 5,541,061, and 6,197,506.

The present invention also contemplates sample preparation methods in certain preferred embodiments. Prior to or concurrent with genotyping, the genomic sample may be amplified by a variety of mechanisms, some of which may employ PCR. See, e.g., PCR Technology: Principles and Applications for DNA Amplification (Ed. H. A. Erlich, Freeman Press, NY, N.Y., 1992); PCR Protocols: A Guide to Methods and Applications (Eds. Innis, et al., Academic Press, San Diego, Calif., 1990); Mattila et al., Nucleic Acids Res. 19, 4967 (1991); Eckert et al., PCR Methods and Applications 1, 17 (1991); PCR (Eds. McPherson et al., IRL Press, Oxford); and U.S. Pat. Nos. 4,683,202, 4,683,195, 4,800,159 4,965,188, and 5,333,675, and each of which is incorporated herein by reference in their entireties for all purposes. The sample may be amplified on the array. See, for example, U.S. Pat. No. 6,300,070 and U.S. patent application Ser. No. 09/513,300, which are incorporated herein by reference.

Other suitable amplification methods include the ligase chain reaction (LCR) (e.g., Wu and Wallace, Genomics 4, 560 (1989), Landegren et al., Science 241, 1077 (1988) and Barringer et al. Gene 89:117 (1990)), transcription amplification (Kwoh et al., Proc. Natl. Acad. Sci. USA 86, 1173 (1989) and WO88/10315), self-sustained sequence replication (Guatelli et al., Proc. Nat. Acad. Sci. USA, 87, 1874 (1990) and WO90/06995), selective amplification of target polynucleotide sequences (U.S. Pat. No. 6,410,276), consensus sequence primed polymerase chain reaction (CP-PCR) (U.S. Pat. No. 4,437,975), arbitrarily primed polymerase chain reaction (AP-PCR) (U.S. Pat. Nos. 5,413,909, 5,861,245) and nucleic acid based sequence amplification (NABSA). (See, U.S. Pat. Nos. 5,409,818, 5,554,517, and 6,063,603, each of which is incorporated herein by reference). Other amplification methods that may be used are described in, U.S. Pat. Nos. 5,242,794, 5,494,810, 4,988,617 and in U.S. Ser. No. 09/854,317, each of which is incorporated herein by reference.

Additional methods of sample preparation and techniques for reducing the complexity of a nucleic sample are described in Dong et al., Genome Research 11, 1418 (2001), in U.S. Pat. No. 6,361,947, 6,391,592 and U.S. patent application Ser. Nos. 09/916,135, 09/920,491, 09/910,292, and 10/013,598.

Methods for conducting polynucleotide hybridization assays have been well developed in the art. Hybridization assay procedures and conditions will vary depending on the application and are selected in accordance with the general binding methods known including those referred to in: Maniatis et al. Molecular Cloning: A Laboratory Manual (2^{nd} Ed. Cold Spring Harbor, N.Y., 1989); Berger and Kimmel Methods in Enzymology, Vol. 152, Guide to Molecular Cloning Techniques (Academic Press, Inc., San Diego, Calif., 1987); Young and Davis, P.N.A.S, 80: 1194 (1983). Methods and apparatus for carrying out repeated and controlled hybridization reactions have been described in U.S. Pat. Nos. 5,871,928, 5,874,219, 6,045,996 and 6,386,749, 6,391,623 each of which are incorporated herein by reference

The present invention also contemplates signal detection of hybridization between ligands in certain preferred embodiments. See U.S. Pat. Nos. 5,143,854, 5,578,832; 5,631,734; 5,834,758; 5,936,324; 5,981,956; 6,025,601; 6,141,096; 6,185,030; 6,201,639; 6,218,803; and 6,225,625, in U.S. patent application 60/364,731 and in PCT Application PCT/US99/06097 (published as WO99/47964), each of which also is hereby incorporated by reference in its entirety for all purposes.

Methods and apparatus for signal detection and processing of intensity data are disclosed in, for example, U.S. Pat. Nos. 5,143,854, 5,547,839, 5,578,832, 5,631,734, 5,800,992, 5,834,758; 5,856,092, 5,902,723, 5,936,324, 5,981,956, 6,025,601, 6,090,555, 6,141,096, 6,185,030, 6,201,639; 6,218,803; and 6,225,625, in U.S. patent application 60/364,731 and in PCT Application PCT/US99/06097 (published as WO99/47964), each of which also is hereby incorporated by reference in its entirety for all purposes.

The practice of the present invention may also employ conventional biology methods, software and systems. Computer software products of the invention typically include computer readable medium having computer-executable instructions for performing the logic steps of the method of the invention. Suitable computer readable medium include floppy disk, CD-ROM/DVD/DVD-ROM, hard-disk drive, flash memory, ROM/RAM, magnetic tapes and etc. The computer executable instructions may be written in a suitable computer language or combination of several languages. Basic computational biology methods are described in, e.g. Setubal and Meidanis et al., Introduction to Computational Biology Methods (PWS Publishing Company, Boston, 1997); Salzberg, Searles, Kasif, (Ed.), Computational Methods in Molecular Biology, (Elsevier, Amsterdam, 1998); Rashidi and Buehler, Bioinformatics Basics: Application in Biological Science and Medicine (CRC Press, London, 2000) and Ouelette and Bzevanis Bioinformatics: A Practical Guide for Analysis of Gene and Proteins (Wiley & Sons, Inc., 2^{nd} ed., 2001). See U.S. Pat. No. 6,420,108.

The present invention may also make use of various computer program products and software for a variety of purposes, such as probe design, management of data, analysis, and instrument operation. See, U.S. Pat. Nos. 5,593,839, 5,795,716, 5,733,729, 5,974,164, 6,066,454, 6,090,555, 6,185,561, 6,188,783, 6,223,127, 6,229,911 and 6,308,170.

The present invention may also make use of the several embodiments of the array or arrays and the processing described in U.S. Pat. Nos. 5,545,531 and 5,874,219. These patents are incorporated herein by reference in their entireties for all purposes.

Additionally, the present invention may have preferred embodiments that include methods for providing genetic information over networks such as the Internet as shown in U.S. patent application Ser. Nos. 10/063,559, 60/349,546, 60/376,003, 60/394,574, 60/403,381.

Definitions

An “array” is an intentionally created collection of molecules which can be prepared either synthetically or biosynthetically. The molecules in the array can be identical or different from each other. The array can assume a variety of formats, e.g., libraries of soluble molecules; libraries of compounds tethered to resin beads, silica chips, or other solid supports.

Array Plate or a Plate a body having a plurality of arrays in which each array is separated from the other arrays by a physical barrier resistant to the passage of liquids and forming an area or space, referred to as a well.

Nucleic acid library or array is an intentionally created collection of nucleic acids which can be prepared either synthetically or biosynthetically and screened for biological activity in a variety of different formats (e.g., libraries of soluble molecules; and libraries of oligos tethered to resin beads, silica chips, or other solid supports). Additionally, the term “array” is meant to include those libraries of nucleic acids which can be prepared by spotting nucleic acids of essentially any length (e.g., from 1 to about 1000 nucleotide monomers in length) onto a substrate. The term “nucleic acid” as used herein refers to a polymeric form of nucleotides of any length, either ribonucleotides, deoxyribonucleotides or peptide nucleic acids (PNAs) as described in U.S. Pat. No. 6,156,501 that comprise purine and pyrimidine bases, or other natural, chemically or biochemically modified, non-natural, or derivatized nucleotide bases. The backbone of the polynucleotide can comprise sugars and phosphate groups, as may typically be found in RNA or DNA, or modified or substituted sugar or phosphate groups. A polynucleotide may comprise modified nucleotides, such as methylated nucleotides and nucleotide analogs. The sequence of nucleotides may be interrupted by non-nucleotide components. Thus the terms nucleoside, nucleotide, deoxynucleoside and deoxynucleotide generally include analogs such as those described herein. These analogs are those molecules having some structural features in common with a naturally occurring nucleoside or nucleotide such that when incorporated into a nucleic acid or oligonucleoside sequence, they allow hybridization with a naturally occurring nucleic acid sequence in solution. Typically, these analogs are derived from naturally occurring nucleosides and nucleotides by replacing and/or modifying the base, the ribose or the phosphodiester moiety. The changes can be tailor made to stabilize or destabilize hybrid formation or enhance the specificity of hybridization with a complementary nucleic acid sequence as desired.

Biopolymer or biological polymer: is intended to mean repeating units of biological or chemical moieties. Representative biopolymers include, but are not limited to, nucleic acids, oligonucleotides, amino acids, proteins, peptides, hormones, oligosaccharides, lipids, glycolipids, lipopolysaccharides, phospholipids, synthetic analogues of the foregoing, including, but not limited to, inverted nucleotides, peptide nucleic acids, Meta-DNA, and combinations of the above. “Biopolymer synthesis” is intended to encompass the synthetic production, both organic and inorganic, of a biopolymer.

Related to a bioploymer is a “biomonomer” which is intended to mean a single unit of biopolymer, or a single unit which is not part of a biopolymer. Thus, for example, a nucleotide is a biomonomer within an oligonucleotide biopolymer, and an amino acid is a biomonomer within a protein or peptide biopolymer; avidin, biotin, antibodies, antibody fragments, etc., for example, are also biomonomers.

Initiation Biomonomer: or “initiator biomonomer” is meant to indicate the first biomonomer which is covalently attached via reactive nucleophiles to the surface of the polymer, or the first biomonomer which is attached to a linker or spacer arm attached to the polymer, the linker or spacer arm being attached to the polymer via reactive nucleophiles.

Complementary: Refers to the hybridization or base pairing between nucleotides or nucleic acids, such as, for instance, between the two strands of a double stranded DNA molecule or between an oligonucleotide primer and a primer binding site on a single stranded nucleic acid to be sequenced or amplified. Complementary nucleotides are, generally, A and T (or A and U), or C and G. Two single stranded RNA or DNA molecules are said to be substantially complementary when the nucleotides of one strand, optimally aligned and compared and with appropriate nucleotide insertions or deletions, pair with at least about 80% of the nucleotides of the other strand, usually at least about 90% to 95%, and more preferably from about 98 to 100%.Alternatively, substantial complementary exists when an RNA or DNA strand will hybridize under selective hybridization conditions to its complement. Typically, selective hybridization will occur when there is at least about 65% complementary over a stretch of at least 14 to 25 nucleotides, preferably at least about 75%, more preferably at least about 90% complementary. See, M. Kanehisa Nucleic Acids Res. 12:203 (1984), incorporated herein by reference.

Combinatorial Synthesis Strategy: A combinatorial synthesis strategy is an ordered strategy for parallel synthesis of diverse polymer sequences by sequential addition of reagents which may be represented by a reactant matrix and a switch matrix, the product of which is a product matrix. A reactant matrix is a 1 column by m row matrix of the building blocks to be added. The switch matrix is all or a subset of the binary numbers, preferably ordered, between 1 and m arranged in columns. A “binary strategy” is one in which at least two successive steps illuminate a portion, often half, of a region of interest on the substrate. In a binary synthesis strategy, all possible compounds which can be formed from an ordered set of reactants are formed. In most preferred embodiments, binary synthesis refers to a synthesis strategy which also factors a previous addition step. For example, a strategy in which a switch matrix for a masking strategy halves regions that were previously illuminated, illuminating about half of the previously illuminated region and protecting the remaining half (while also protecting about half of previously protected regions and illuminating about half of previously protected regions). It will be recognized that binary rounds may be interspersed with non-binary rounds and that only a portion of a substrate may be subjected to a binary scheme. A combinatorial “masking” strategy is a synthesis which uses light or other spatially selective deprotecting or activating agents to remove protecting groups from materials for addition of other materials such as amino acids.

Effective amount refers to an amount sufficient to induce a desired result.

Excitation energy refers to energy used to energize a detectable label for detection, for example illuminating a fluorescent label. Devices for this use include coherent light or non coherent light, such as lasers, UV light, light emitting diodes, an incandescent light source, or any other light or other electromagnetic source of energy having a wavelength in the excitation band of an excitable label, or capable of providing detectable transmitted, reflective, or diffused radiation.

Genome is all the genetic material in the chromosomes of an organism. DNA derived from the genetic material in the chromosomes of a particular organism is genomic DNA. A genomic library is a collection of clones made from a set of randomly generated overlapping DNA fragments representing the entire genome of an organism.

Hybridization conditions will typically include salt concentrations of less than about 1M, more usually less than about 500 mM and preferably less than about 200 mM. Hybridization temperatures can be as low as 5° C., but are typically greater than 22° C., more typically greater than about 30° C., and preferably in excess of about 37° C. Longer fragments may require higher hybridization temperatures for specific hybridization. As other factors may affect the stringency of hybridization, including base composition and length of the complementary strands, presence of organic solvents and extent of base mismatching, the combination of parameters is more important than the absolute measure of any one alone.

Hybridizations, e.g., allele-specific probe hybridizations, are generally performed under stringent conditions. For example, conditions where the salt concentration is no more than about 1 Molar (M) and a temperature of at least 25° C., e.g., 750 mM NaCl, 50 mM NaPhosphate, 5 mM EDTA, pH 7.4 (5×SSPE) and a temperature of from about 25° C. to about 30° C.

Hybridizations are usually performed under stringent conditions, for example, at a salt concentration of no more than 1 M and a temperature of at least 25° C. For example, conditions of 5× SSPE (750 mM NaCl, 50 mM NaPhosphate, 5 mM EDTA, pH 7.4) and a temperature of 25-30° C. are suitable for allele-specific probe hybridizations. For stringent conditions, see, for example, Sambrook, Fritsche and Maniatis. “Molecular Cloning: A laboratory Manual” 2^{nd} Ed. Cold Spring Harbor Press (1989) which is hereby incorporated by reference in its entirety for all purposes above.

The term “hybridization” refers to the process in which two single-stranded polynucleotides bind non-covalently to form a stable double-stranded polynucleotide; triple-stranded hybridization is also theoretically possible. The resulting (usually) double-stranded polynucleotide is a “hybrid.” The proportion of the population of polynucleotides that forms stable hybrids is referred to herein as the “degree of hybridization.”

Hybridization probes are oligonucleotides capable of binding in a base-specific manner to a complementary strand of nucleic acid. Such probes include peptide nucleic acids, as described in Nielsen et al., Science 254, 1497-1500 (1991), and other nucleic acid analogs and nucleic acid mimetics. See U.S. Pat. No. 6,156,501.

Hybridizing specifically to: refers to the binding, duplexing, or hybridizing of a molecule substantially to or only to a particular nucleotide sequence or sequences under stringent conditions when that sequence is present in a complex mixture (e.g., total cellular) DNA or RNA.

Isolated nucleic acid is an object species invention that is the predominant species present (i.e., on a molar basis it is more abundant than any other individual species in the composition). Preferably, an isolated nucleic acid comprises at least about 50, 80 or 90% (on a molar basis) of all macromolecular species present. Most preferably, the object species is purified to essential homogeneity (contaminant species cannot be detected in the composition by conventional detection methods).

Label for example, a luminescent label, a light scattering label or a radioactive label. Fluorescent labels include, inter alia, the commercially available fluorescein phosphoramidites such as Fluoreprime (Pharmacia), Fluoredite (Millipore) and FAM (ABI). See U.S. Pat. No. 6,287,778.

Ligand: A ligand is a molecule that is recognized by a particular receptor. The agent bound by or reacting with a receptor is called a “ligand,” a term which is definitionally meaningful only in terms of its counterpart receptor. The term “ligand” does not imply any particular molecular size or other structural or compositional feature other than that the substance in question is capable of binding or otherwise interacting with the receptor. Also, a ligand may serve either as the natural ligand to which the receptor binds, or as a functional analogue that may act as an agonist or antagonist. Examples of ligands that can be investigated by this invention include, but are not restricted to, agonists and antagonists for cell membrane receptors, toxins and venoms, viral epitopes, hormones (e.g., opiates, steroids, etc.), hormone receptors, peptides, enzymes, enzyme substrates, substrate analogs, transition state analogs, cofactors, drugs, proteins, and antibodies.

Linkage disequilibrium or allelic association means the preferential association of a particular allele or genetic marker with a specific allele, or genetic marker at a nearby chromosomal location more frequently than expected by chance for any particular allele frequency in the population. For example, if locus X has alleles a and b, which occur equally frequently, and linked locus Y has alleles c and d, which occur equally frequently, one would expect the combination ac to occur with a frequency of 0.25. If ac occurs more frequently, then alleles a and c are in linkage disequilibrium. Linkage disequilibrium may result from natural selection of certain combination of alleles or because an allele has been introduced into a population too recently to have reached equilibrium with linked alleles.

Microtiter plates are arrays of discrete wells that come in standard formats (96, 384 and 1536 wells) which are used for examination of the physical, chemical or biological characteristics of a quantity of samples in parallel.

Mixed population or complex population: refers to any sample containing both desired and undesired nucleic acids. As a non-limiting example, a complex population of nucleic acids may be total genomic DNA, total genomic RNA or a combination thereof. Moreover, a complex population of nucleic acids may have been enriched for a given population but include other undesirable populations. For example, a complex population of nucleic acids may be a sample which has been enriched for desired messenger RNA (mRNA) sequences but still includes some undesired ribosomal RNA sequences (rRNA).

Monomer: refers to any member of the set of molecules that can be joined together to form an oligomer or polymer. The set of monomers useful in the present invention includes, but is not restricted to, for the example of (poly)peptide synthesis, the set of L-amino acids, D-amino acids, or synthetic amino acids. As used herein, “monomer” refers to any member of a basis set for synthesis of an oligomer. For example, dimers of L-amino acids form a basis set of 400 “monomers” for synthesis of polypeptides. Different basis sets of monomers may be used at successive steps in the synthesis of a polymer. The term “monomer” also refers to a chemical subunit that can be combined with a different chemical subunit to form a compound larger than either subunit alone.

mRNA or mRNA transcripts: as used herein, include, but not limited to pre-mRNA transcript(s), transcript processing intermediates, mature mRNA(s) ready for translation and transcripts of the gene or genes, or nucleic acids derived from the mRNA transcript(s). Transcript processing may include splicing, editing and degradation. As used herein, a nucleic acid derived from an mRNA transcript refers to a nucleic acid for whose synthesis the mRNA transcript or a subsequence thereof has ultimately served as a template. Thus, a cDNA reverse transcribed from an mRNA, an RNA transcribed from that cDNA, a DNA amplified from the cDNA, an RNA transcribed from the amplified DNA, etc., are all derived from the mRNA transcript and detection of such derived products is indicative of the presence and/or abundance of the original transcript in a sample. Thus, mRNA derived samples include, but are not limited to, mRNA transcripts of the gene or genes, cDNA reverse transcribed from the mRNA, cRNA transcribed from the cDNA, DNA amplified from the genes, RNA transcribed from amplified DNA, and the like.

Nucleic acid library or array is an intentionally created collection of nucleic acids which can be prepared either synthetically or biosynthetically and screened for biological activity in a variety of different formats (e.g., libraries of soluble molecules; and libraries of oligos tethered to resin beads, silica chips, or other solid supports). Additionally, the term “array” is meant to include those libraries of nucleic acids which can be prepared by spotting nucleic acids of essentially any length (e.g., from 1 to about 1000 nucleotide monomers in length) onto a substrate. The term “nucleic acid” as used herein refers to a polymeric form of nucleotides of any length, either ribonucleotides, deoxyribonucleotides or peptide nucleic acids (PNAs), that comprise purine and pyrimidine bases, or other natural, chemically or biochemically modified, non-natural, or derivatized nucleotide bases. The backbone of the polynucleotide can comprise sugars and phosphate groups, as may typically be found in RNA or DNA, or modified or substituted sugar or phosphate groups. A polynucleotide may comprise modified nucleotides, such as methylated nucleotides and nucleotide analogs. The sequence of nucleotides may be interrupted by non-nucleotide components. Thus the terms nucleoside, nucleotide, deoxynucleoside and deoxynucleotide generally include analogs such as those described herein. These analogs are those molecules having some structural features in common with a naturally occurring nucleoside or nucleotide such that when incorporated into a nucleic acid or oligonucleoside sequence, they allow hybridization with a naturally occurring nucleic acid sequence in solution. Typically, these analogs are derived from naturally occurring nucleosides and nucleotides by replacing and/or modifying the base, the ribose or the phosphodiester moiety. The changes can be tailor made to stabilize or destabilize hybrid formation or enhance the specificity of hybridization with a complementary nucleic acid sequence as desired.

Nucleic acids according to the present invention may include any polymer or oligomer of pyrimidine and purine bases, preferably cytosine, thymine, and uracil, and adenine and guanine, respectively. See Albert L. Lehninger, Principles of Biochemistry, at 793-800 (Worth Pub. 1982). Indeed, the present invention contemplates any deoxyribonucleotide, ribonucleotide or peptide nucleic acid component, and any chemical variants thereof, such as methylated, hydroxymethylated or glucosylated forms of these bases, and the like. The polymers or oligomers may be heterogeneous or homogeneous in composition, and may be isolated from naturally-occurring sources or may be artificially or synthetically produced. In addition, the nucleic acids may be DNA or RNA, or a mixture thereof, and may exist permanently or transitionally in single-stranded or double-stranded form, including homoduplex, heteroduplex, and hybrid states.

An “oligonucleotide” or “polynucleotide” is a nucleic acid ranging from at least 2, preferable at least 8, and more preferably at least 20 nucleotides in length or a compound that specifically hybridizes to a polynucleotide. Polynucleotides of the present invention include sequences of deoxyribonucleic acid (DNA) or ribonucleic acid (RNA) which may be isolated from natural sources, recombinantly produced or artificially synthesized and mimetics thereof. A further example of a polynucleotide of the present invention may be peptide nucleic acid (PNA). The invention also encompasses situations in which there is a nontraditional base pairing such as Hoogsteen base pairing which has been identified in certain tRNA molecules and postulated to exist in a triple helix. “Polynucleotide” and “oligonucleotide” are used interchangeably in this application.

Probe: A probe is a surface-immobilized molecule that can be recognized by a particular target. Examples of probes that can be investigated by this invention include, but are not restricted to, agonists and antagonists for cell membrane receptors, toxins and venoms, viral epitopes, hormones (e.g., opioid peptides, steroids, etc.), hormone receptors, peptides, enzymes, enzyme substrates, cofactors, drugs, lectins, sugars, oligonucleotides, nucleic acids, oligosaccharides, proteins, and monoclonal antibodies.

Primer is a single-stranded oligonucleotide capable of acting as a point of initiation for template-directed DNA synthesis under suitable conditions e.g., buffer and temperature, in the presence of four different nucleoside triphosphates and an agent for polymerization, such as, for example, DNA or RNA polymerase or reverse transcriptase. The length of the primer, in any given case, depends on, for example, the intended use of the primer, and generally ranges from 15 to 20, 25, 30 nucleotides. Short primer molecules generally require cooler temperatures to form sufficiently stable hybrid complexes with the template. A primer need not reflect the exact sequence of the template but must be sufficiently complementary to hybridize with such template. The primer site is the area of the template to which a primer hybridizes. The primer pair is a set of primers including a 5′ upstream primer that hybridizes with the 5′ end of the sequence to be amplified and a 3′ downstream primer that hybridizes with the complement of the 3′ end of the sequence to be amplified.

Polymorphism refers to the occurrence of two or more genetically determined alternative sequences or alleles in a population. A polymorphic marker or site is the locus at which divergence occurs. Preferred markers have at least two alleles, each occurring at frequency of greater than 1%, and more preferably greater than 10% or 20% of a selected population. A polymorphism may comprise one or more base changes, an insertion, a repeat, or a deletion. A polymorphic locus may be as small as one base pair. Polymorphic markers include restriction fragment length polymorphisms, variable number of tandem repeats (VNTR's), hypervariable regions, minisatellites, dinucleotide repeats, trinucleotide repeats, tetranucleotide repeats, simple sequence repeats, and insertion elements such as Alu. The first identified allelic form is arbitrarily designated as the reference form and other allelic forms are designated as alternative or variant alleles. The allelic form occurring most frequently in a selected population is sometimes referred to as the wildtype form. Diploid organisms may be homozygous or heterozygous for allelic forms. A diallelic polymorphism has two forms. A triallelic polymorphism has three forms. Single nucleotide polymorphisms (SNPs) are included in polymorphisms.

Reader or plate reader is a device which is used to identify hybridization events on an array, such as the hybridization between a nucleic acid probe on the array and a fluorescently labeled target. Readers are known in the art and are commercially available through Affymetrix, Santa Clara Calif. and other companies. Generally, they involve the use of an excitation energy (such as a laser) to illuminate a fluorescently labeled target nucleic acid that has hybridized to the probe. Then, the reemitted radiation (at a different wavelength than the excitation energy) is detected using devices such as a CCD, PMT, photodiode, or similar devices to register the collected emissions. See U.S. Pat. No. 6,225,625.

Receptor: A molecule that has an affinity for a given ligand. Receptors may be naturally-occurring or manmade molecules. Also, they can be employed in their unaltered state or as aggregates with other species. Receptors may be attached, covalently or noncovalently, to a binding member, either directly or via a specific binding substance. Examples of receptors which can be employed by this invention include, but are not restricted to, antibodies, cell membrane receptors, monoclonal antibodies and antisera reactive with specific antigenic determinants (such as on viruses, cells or other materials), drugs, polynucleotides, nucleic acids, peptides, cofactors, lectins, sugars, polysaccharides, cells, cellular membranes, and organelles. Receptors are sometimes referred to in the art as anti-ligands. As the term receptors is used herein, no difference in meaning is intended. A “Ligand Receptor Pair” is formed when two macromolecules have combined through molecular recognition to form a complex. Other examples of receptors which can be investigated by this invention include but are not restricted to those molecules shown in U.S. Pat. No. 5,143,854, which is hereby incorporated by reference in its entirety.

“Peg” is a support member for a sensor.

“Sensor” is a device that provides a location of the measurement that can be made. Labeling and scanning can be part of the method of obtaining the data. (from Lisa)

“Sensor cartridge” refers to a body forming an area or space referred to as a well wherein a sensor is contained. Optionally, the cartridge may contain a space for a fluid such as a target sample or a buffer. The term “well” as used herein can refer to a chamber. The sensor cartridge can also comprise a lid.

“Sensor peg” is an assembly of a sensor and a support member. It can be inserted into a device (such as a sensor cartridge) where a reaction can occur. Usually, the sensor peg is immersed into the sensor cartridge with the active area of the sensor facing out into the well of the sensor cartridge.

“Solid support”, “support”, and “substrate” are used interchangeably and refer to a material or group of materials having a rigid or semi-rigid surface or surfaces. In many embodiments, at least one surface of the solid support will be substantially flat, although in some embodiments it may be desirable to physically separate synthesis regions for different compounds with, for example, wells, raised regions, pins, etched trenches, or the like. According to other embodiments, the solid support(s) will take the form of beads, resins, gels, microspheres, or other geometric configurations. See U.S. Pat. No. 5,744,305 for exemplary substrates.

Target: A molecule that has an affinity for a given probe. Targets may be naturally-occurring or man-made molecules. Also, they can be employed in their unaltered state or as aggregates with other species. Targets may be attached, covalently or noncovalently, to a binding member, either directly or via a specific binding substance. Examples of targets which can be employed by this invention include, but are not restricted to, antibodies, cell membrane receptors, monoclonal antibodies and antisera reactive with specific antigenic determinants (such as on viruses, cells or other materials), drugs, oligonucleotides, nucleic acids, peptides, cofactors, lectins, sugars, polysaccharides, cells, cellular membranes, and organelles. Targets are sometimes referred to in the art as anti-probes. As the term targets is used herein, no difference in meaning is intended. A “Probe Target Pair” is formed when two macromolecules have combined through molecular recognition to form a complex.

WGSA (Whole Genome Sampling Assay) Genotyping Technology: A technology that allows the genotyping of hundreds of thousands of SNPs simultaneously in complex DNA without the use of locus-specific primers. In this technique, genomic DNA, for example, is digested with a restriction enzyme of interest and adaptors are ligated to the digested fragments. A single primer corresponding to the adaptor sequence is used to amplify fragments of a desired size, for example, 500-2000 bp. The processed target is then hybridized to nucleic acid arrays comprising SNP-containing fragments/probes. WGSA is disclosed in, for example, U.S. Provisional Application Ser. Nos. 60/319,685, 60/453,930, 60/454,090 and 60/456,206, 60/470,475, U.S. patent application Ser. Nos. 09/766,212, 10/316,517,10/316,629, 10/463,991, 10/321,741, 10/442,021 and 10/264,945, each of which is hereby incorporated by reference in its entirety for all purposes.

Whole Transcript Assay (WTA): As used herein, a WTA is an assay protocol that can representatively sample entire transcripts (i.e., all exons in a transcript).

Reference will now be made in detail to exemplary embodiments of the invention. While the invention will be described in conjunction with the exemplary embodiments, it will be understood that they are not intended to limit the invention to these embodiments. On the contrary, the invention is intended to cover alternatives, modifications and equivalents, which may be included within the spirit and scope of the invention.

II. Device and Method for Immersed Array Packaging and Processing

The present invention provides devices and methods for processing and packaging sensors. In one embodiment, the present invention provides a sensor peg and at least one associated sensor cartridge for processing the sensor. The sensor peg comrises a “sensor” and a “peg”. The peg is a support member for the sensor. Usually, the material of the peg is different from the material of the sensor.

There can be various types of sensors, including “nucleic acid sensors” which can refer to a nucleic acid microarrays, “DNA sensors” which can refer to a DNA microarrays and “oligonucleotide sensors” which can refer to oligonucleotide micro-arrays. The sensor can be made out of plastic, metal, silicon and the like. The material of the sensor can be non-transparent. The sensor is usually attached to an end of the support member (peg) and assembled with the active side up facing out. In addition, the shape of the support member and the sensor can vary. In preferred embodiments, the sensor is a microarray chip. An example of a microarray chip is the chip sold by Affymetrix Inc. (Santa Clara, Calif.) under the brand name GeneChip®. Methods for manufacturing microarray chips and their applications are described in several publications, patents and patent applications, previously incorporated by reference.

The term support member as used herein can comprise a device that supports at least one sensor; the support is suitable to hold the sensor onto a body wherein a reaction can occur. The pegs or support members may be used individually or may form part of a holding device such as a microarray plate as described in U.S. patent application Ser. No. 10/826,577, entitled “Immersion Array Plates for Interchangeable Microtiter Well Plates”, filed on Apr. 16, 2004 and incorporated herein by reference in its entirety for all purposes. The peg material can be made from any material that is compatible with the chemical reactants and solvents that are placed in the sensor cartridge wells. Any of a variety of organic or inorganic materials or combinations thereof, may be employed for the peg including, for example, metal, plastics, such as polypropylene, polystyrene, polyvinyl chloride, polycarbonate, polysulfone, etc.; nylon; PTFE, ceramic; silicon; (fused) silica, quartz or glass, and the like. The peg may be of any shape, for example, rectangular, square, circular, oval, and so forth. By way of illustration and not limitation, the dimensions of the support members can be 0.25 mm to about 15 mm in length, width and depth.

The chip (sensor) may be attached to the peg by any means known in the art, for example, an adhesive. The adhesive, for example, may be silicone, adhesive tape, or other adhesive. Alternatively, other mounting techniques such as ultrasonic welding, for example, may be employed.

The sensor peg is placed in a sensor cartridge well for further processing. In a preferred embodiment, the sensor cartridge well comprises a casing with a cavity or space therein. This cavity may be referred to as a well. The term “well” as used herein may refer to a chamber. A sensor may be contained in the well or fluids may be introduced and retained therein. These fluids may be used for processing the sensor in a series of reaction steps. The reaction steps comprise: hybridizing the chip to a target sample, washing the chip to remove non-specifically bound target molecules, staining the chip, optionally washing the chip again to remove any excess stain and finally, scanning the chip. Accordingly, the fluids can comprise, for example, a DNA or RNA sample prepared from the target to be analyzed (for the hybridization step) or a buffer for washing the chip or a buffer for staining and scanning the chip. The cavity is preferably located substantially at the centre of the casing. The sensor is immersed into the fluids in the sensor cartridge wells, effectively forming individual reaction chambers. The size of the array and the geometry of the cartridge wells defines the volume of the fluids in the wells. The sensor cartridge wells are filled with fluids so that contact is made between the liquid samples and the sensor.

Similar to the sensor pegs, a plurality of sensor cartridges can also be mounted onto a holding device such as a hybridization plate, a washing plate, a staining plate or a detection plate as described in U.S. patent application Ser. No. 10/826,577, entitled “Immersion Array Plates for Interchangeable Microtiter Well Plates”, filed on Apr. 16, 2004 and incorporated herein by reference in its entirety for all purposes. This configuration is more suitable for larger sensors or sensors which comprise more information.

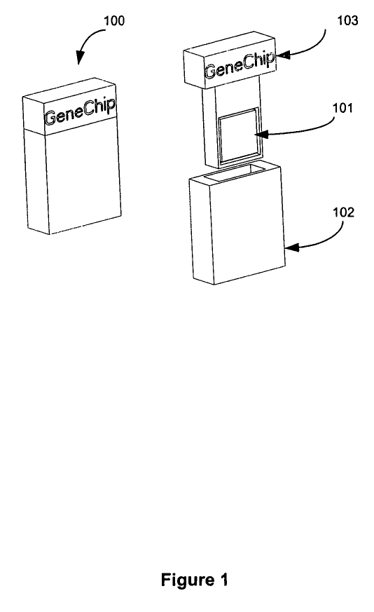

FIG. 1 depicts a preferred embodiment of the sensor peg and its associated sensor cartridge well according to the present invention. The peg or support member comprises a thin, rectangularly shaped body to which the sensor (101) is coplanarly attached. This design makes the orientation of the sensor vertical when the sensor peg is immersed in a sensor cartridge well (102). The shape of the sensor cartridge well is preferably rectangular.

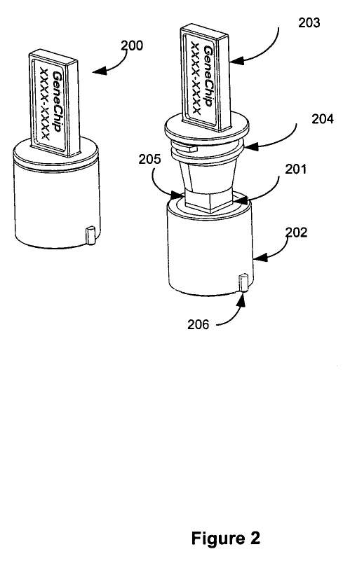

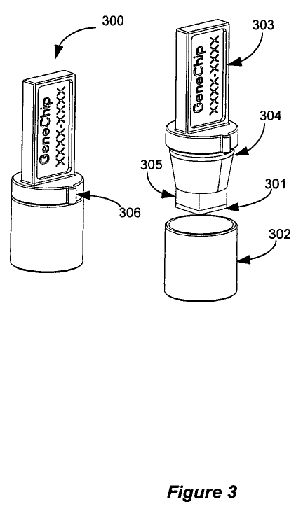

Another preferred embodiment of the sensor peg and its associated sensor cartridge well according to the present invention, is depicted in FIGS. 2 and 3. In this embodiment, the sensor peg design (200, 300) comprises a support member which further comprises a substantially cylindrical assembly of two members, a sealing member (204, 304) and a base member (205, 305) for supporting the sensor. The sensor (201, 301) in this design is mounted horizontally onto the base member (205, 305) of the cylindrical peg assembly. For this embodiment of the peg sensor, the shape of the sensor cartridge well (202, 302) is preferably cylindrical. The sensor peg assemblies depicted in FIGS. 2 and 3 will be broadly referred to as “cylindrical pegs” henceforth.

Both the rectangular and cylindrical sensor pegs are preferably sealed to their respective sensor cartridges during the hybridization step so as to minimize loss of fluids from the cartridge wells. In one embodiment, as depicted in FIG. 2, the cylindrical sensor peg may comprise a luer fitting design feature (204) which can be twisted a quarter turn, for example, to seal the peg into the cartridge. In another embodiment, as depicted in FIG. 3, the cylindrical sensor peg may comprise a seal with a press fit feature (304). The luer fitting feature (204) and the press fit feature (304) may be incorporated into the support member.

In another embodiment of cylindrical sensor peg, the peg or support member is hollow and the active side of the sensor is facing down into the support member whereas the walls and the sensor create a well which liquid can be contained. This configuration would be included under sensor cartridge and would not require a window to be scanned since it would be scanned from the back of the window. For this embodiment, an adhesive may be used to bond the glass with the arrays to a plastic (Lexan HP1) surface of the peg. The microarray can also be made of a different type of plastic compared to the plastic that the support member is made of. Because the back surface (non-active side) of the microarray is the bonding surface, the adhesive must be low-fluorescent at the working emission wavelengths of the hybridized, labeled probe arrays.

One of skill in the art would understand that the present invention encompasses variations of the rectangular and cylindrical designs described above and is by no means limited to the same. Both the rectangular and cylindrical designs can minimize the internal fluidic volumes, which depend on the array size as well as the geometry of the sensor cartridge wells. For example, the volumes may be as low as 5-10 μl for a 3 mm square array.

In a particularly preferred embodiment, a different sensor cartridge well is used for each reaction step (hybridization, washing, staining and scanning). One of skill in the art would appreciate that the same sensor cartridge well may be used for all the reaction steps. Using a different sensor cartridge well for each reaction step potentially reduces cross-contamination between the reaction steps, thereby allowing array images with reduced chemical background and noise. The sensor cartridge wells may be disposable. Preferably, the sensor cartridges are made from injection molded plastic or the like. Thus, the present invention contemplates microarray chips that may be processed by sequential immersion in a plurality of sensor cartridges, thereby allowing efficient cleaning of the chips and images with reduced chemical background or noise.

A sensor cartridge well used for the hybridization reaction step (hybridization sensor cartridge) should preferably be made of a material that can resist the hybridization temperature. The term “hybridization temperature” as used herein is the temperature that is suitable for the hybridization of the sensor. Hybridization temperatures can be typically as low as 5° C., but are typically greater than 22° C., more typically greater than about 30° C., and preferably in excess of about 70° C. Additionally, the hybridization sensor cartridge may be made from any material that is compatible with the chemical reactants and solvents that are placed in the wells. Any of a variety of organic or inorganic materials or combinations thereof, may be employed for the cartridge including, for example, plastics, such as polypropylene, polystyrene, polycarbonate, polypropylene, polyvinyl chloride, etc.; nylon; PTFE, ceramic; silicon; (fused) silica, quartz or glass, and the like. In a preferred embodiment, the hybridization sensor cartridge is made out of Lexan HPI which allows the cartridge to withstand high temperatures for hybridization, and cold temperatures for storage. This material enables hybridization conditions at temperatures in excess of 60° C. In another preferred embodiment, the hybridization sensor cartridge may be suitable for chemiluminescence.

After hybridization process, the sensor peg is transferred to the detection sensor cartridge. The sensor cartridge used for scanning or detection preferably comprises a window of optically clear and low-fluorescence material such as fused silica, zeonor (Zeonor 1020R, zionex) etc. The optically clear window is preferably transparent and distortion-free for purposes of imaging the surface of the sensors. This material should preferably also be non-fluorescent in order to minimize the background signal level and allow detection of low level signals from low intensity features of the sensor.

In other preferred embodiments, features for tracking the sensor pegs may be provided. These features include, for example, identification tabs (103, 203, 303) as depicted in FIGS. 1-3 and may be present on the peg (support member). These identification tabs may include information such as product and tracking information, a radio frequency identification detector (RFID) and so forth. Preferably, the tabs would be of a size large enough to accommodate appropriately prominent label sizes. Even more preferably, the tabs would incorporate features to make the sensor peg-sensor-cartridge assembly amenable to automation or robotic handling.

In yet other embodiments, support structures or alignment holes may exist at selected locations on the sensor peg and/or sensor cartridge. Examples of such alignment/support structures are depicted in FIG. 2 (206) where the structure is located on the sensor cartridge, and FIG. 3 (306) where the structure is located on the sensor peg. These support structures may be used to mount or position the chip packaging device to an apparatus, e.g. scanner or the like. Thereafter, the package may be aligned on a detection or imaging system, such as those disclosed in U.S. Pat. Nos. 5,578,832, 6,025,601 and 6,225,625, all incorporated herein by reference. Such a detection system may include a holder to match the shape of the sensor peg-sensor cartridge assembly to ensure proper orientation and alignment for scanning. The rectangular-shaped sensor peg, for example, is compatible with scanning instruments such as GeneChip® Scanner 3000 (Affymetrix Inc., Santa Clara, Calif.) or GeenArray® 2500 (Agilent Inc., Palo Alto, Calif.).

In comparing front-side scanning to backside scanning, back-side scanning has the advantage of not requiring a window to scan. An example of front-side scanning is a sensor cartridge incorporating a sensor peg with the active the side exposed facing into the well of the cartridge. The buffer is contained in the well of the cartridge while the DNA chip is scanned through the window. Experiments were performed to show that the performance results of the sensor cartridge built up with a sensor peg was comparable to that of a standard DNA microarray chip.

### CONCLUSION

The present invention provides devices and methods for packaging and processing microarray chips. It is to be understood that the above description is intended to be illustrative and not restrictive. Many variations of the invention will be apparent to those of skill in the art upon reviewing the above description. All cited references, including patent and non-patent literature, are incorporated herein by reference in their entireties for all purposes.

1. A packaging device comprising:
a peg member;
a sensor; wherein the sensor is mounted on the peg member to form a sensor peg; and
at least one cartridge; wherein the sensor peg is immersed into the cartridge for a plurality of processing steps.

2. The device of claim 1 wherein the sensor is a microarray chip.

3. The device of claim 2 wherein the peg member is rectangular.

4. The device of claim 3 wherein the cartridge is rectangular.

5. The device of claim 4 wherein the sensor is mounted coplanarly on the rectangular peg member such that the sensor peg is immersed vertically into the cartridge.

6. The device of claim 5 wherein the sensor is mounted with an adhesive.

7. The device of claim 6 wherein the peg member is made of plastic.

8. The device of claim 7 wherein the cartridge is made of plastic.

9. The device of claim 8 wherein the rectangular sensor peg is sealed to the cartridge.

10. The device of claim 2 wherein the peg member is cylindrical.

11. The device of claim 10 wherein the cartridge is cylindrical.

12. The device of claim 11 wherein the sensor is mounted horizontally onto the bottom of the cylindrical peg member.

13. The device of claim 12 wherein the sensor is mounted with an adhesive.

14. The device of claim 13 wherein the peg member is made of plastic.

15. The device of claim 13 wherein the cartridge is made of plastic.

16. The device of claim 15 wherein the cylindrical sensor peg is sealed to the cartridge.

17. The device of claim 16 wherein the cylindrical peg member includes a luer fitting feature to enable sealing by a twisting mechanism.

18. The device of claim 16 wherein the cylindrical peg member includes a press fit feature.

19. The device of claim 2 wherein the peg sensor further comprises an identification tab.

20. The device of claim 19 wherein the identification tab includes a radio frequency identification detector (RFID).

21. The device of claim 19 wherein the identification tab includes a feature to enable automation.

22. The device of claim 19 wherein the identification tab includes a feature to enable robotic handling.

23. The device of claim 2 wherein the plurality of processing steps include hybridization, washing, staining and scanning.

24. The device of claim 23 wherein a different cartridge is used for each processing step.

25. A method for processing a sensor peg comprising:
providing a plurality of cartridges containing fluids therein;
sequentially immersing the sensor peg into the plurality of cartridges; and
providing suitable conditions for carrying out the reaction steps of hybridization,
washing, staining and scanning in the plurality of cartridges.

26. The method of claim 25 wherein the sensor peg comprises a microarray chip.

27. The method of claim 26 wherein the microarray chip is 3 mm by 3 mm.

28. The method of claim 27 wherein a different cartridge is used for each of the reaction steps.

29. The method of claim 28 wherein the volume of the fluid in a cartridge is less than 10 μl.
